(19) United States
(12) Patent Application Publication
(10) Pub. No.: US 2026/0156929 A1
(43) Pub. Date: Jun. 4, 2026

(54) GROUP III-V POWER SEMICONDUCTOR DEVICE AND METHOD OF MANUFACTURING SAME

(71) Applicant: DB HiTek Co., Ltd., Bucheon-si (KR)

(72) Inventors: Min Su CHO, Eumseong-gun (KR); Jong Hyun LEE, Eumseong-gun (KR); Woo Chul JEON, Eumseong-gun (KR); Ji Houn JUNG, Eumseong-gun (KR); Ung Bi SON, Eumseong-gun (KR); Jun Hyeok LEE, Eumseong-gun (KR); Dong Hyeok SON, Eumseong-gun (KR)

(21) Appl. No.: 19/062,238

(22) Filed: Feb. 25, 2025

(30) Foreign Application Priority Data
Dec. 2, 2024 (KR) 10-2024-0176207

(51) Int. Cl. H10D 84/84; H10D 30/01; H10D 30/47; H10D 62/824; H10D 64/27; H10D 64/62

(52) U.S. Cl. CPC H10D 84/84; H10D 30/015; H10D 30/475; H10D 62/824; H10D 64/411; H10D 64/62

(57) ABSTRACT

Proposed are a group III-V power semiconductor device and a method of manufacturing the same. More particularly, proposed are a group III-V power semiconductor device in which regions that differ from each other in threshold voltage characteristics are implemented on a single wafer, and to a method of manufacturing the same.

### CROSS REFERENCE TO RELATED APPLICATION

The present application claims priority to Korean Patent Application No. 10-2024-0176207, filed Dec. 2, 2024, the entire contents of which is incorporated herein for all purposes by this reference.

### BACKGROUND

### Technical Field

The present disclosure relates to a group III-V power semiconductor device and a method of manufacturing the same. More particularly, the present disclosure relates to a group III-V power semiconductor device in which regions that differ from each other in threshold voltage characteristics are implemented on a single wafer, and to a method of manufacturing the same.

### Description of the Related Art

Nitride-based semiconductors are being applied to high-withstand voltage and high-power semiconductor devices through high electron saturation velocity and wide band gap characteristics. In particular, gallium nitride (GaN) has high breakdown field characteristics and wide band gap characteristics compared to silicon and gallium arsenide (GaAs) and thus exhibits excellent breakdown voltage characteristics when applied to transistors.

In addition, GaN-based devices have high electron mobility and electron saturation velocity compared to silicon-based devices, which are currently commonly available, and therefore, can exhibit high frequency characteristics. In addition, the application of such high electron mobility to GaN-based devices allows for improved on-resistance characteristics, thereby enabling the implementation of low-loss switching devices. As described above, GaN-based field effect transistors (FETs) are sufficiently advantageous as devices that require high-frequency and high-power characteristics, so ongoing research is in progress.

Existing nitride-based power semiconductor devices have limitations in that only one threshold voltage characteristic is obtainable on a single wafer.

To solve such a problem, the inventors of the present disclosure have proposed a novel group III-V power semiconductor device and a method of manufacturing the same, the contents of which will be described in detail later.

### DOCUMENTS OF RELATED ART

### [Patent Document]

Korean Patent Application Publication No. 10-2020-0068745 “High-Electron-Mobility Transistor”

### SUMMARY

The present disclosure, which has been devised to address the above-described issues in the related art, aims to provide a group III-V power semiconductor device in which regions that differ from each other in threshold voltage characteristics are implemented on a single wafer, and a method of manufacturing the same.

In addition, the present disclosure aims to provide a group III-V power semiconductor device in which a deactivated region is formed within a second region, thereby preventing damage to a barrier layer in advance when forming a gate electrode, and a method of manufacturing the same.

In addition, the present disclosure aims to provide a group III-V power semiconductor device in which the entire region of a second capping layer to be formed within a second region is formed as a deactivated region, thereby enabling regions that operate both in a depletion mode (D-mode) and an enhancement mode (E-mode) to be formed on a single wafer, and a method of manufacturing the same.

In addition, the present disclosure aims to provide a group III-V power semiconductor device in which a deactivated region is enabled to be formed in conjunction with an isolation film through the same process in some cases, thereby preventing the overall process efficiency from being reduced, and a method of manufacturing the same.

In addition, the present disclosure aims to provide a group III-V power semiconductor device in which a deactivated region is enabled to be formed in various patterns in a second capping layer, thereby easily controlling the threshold voltage of a second region to a desired level, and a method of manufacturing the same.

The present disclosure may be implemented by embodiments having the following configurations to achieve the above-described objectives.

In one embodiment of the present disclosure, a group III-V power semiconductor device, according to the present disclosure, is characterized by including: a first region; a second region that differs from the first region in threshold voltage characteristics; a substrate within the first and second regions; a channel layer on the substrate within the first and second regions; a barrier layer on the channel layer within the first and second regions; a capping layer on the barrier layer within the first region; a first gate electrode on the capping layer, a deactivated region on the barrier layer within the second region; and a second gate electrode on the deactivated region.

In another embodiment of the present disclosure, the group III-V power semiconductor device, according to the present disclosure, is characterized in that the second region is a region that operates in a D-mode.

In a further embodiment of the present disclosure, the group III-V power semiconductor device, according to the present disclosure, is characterized in that the deactivated region is an ion implantation region for a p-GaN layer.

In a further embodiment of the present disclosure, the group III-V power semiconductor device, according to the present disclosure, is characterized in that the deactivated region is a region where one or more elements of Ar, N, O, Si, and H are implanted through ion implantation.

In a further embodiment of the present disclosure, a group III-V power semiconductor device, according to the present disclosure, is characterized by including: a first region; a second region that differs from the first region in threshold voltage characteristics; a substrate within the first and second regions; a channel layer on the substrate within the first and second regions; a barrier layer on the channel layer within the first and second regions; a first capping layer on the barrier layer within the first region; a first gate electrode on the first capping layer; a second capping layer on the barrier layer within the second region; a deactivated region in the second capping layer; and a second gate electrode on the deactivated region.

In a further embodiment of the present disclosure, the group III-V power semiconductor device, according to the present disclosure, is characterized in that the deactivated region is an ion implantation region in the second capping layer.

In a further embodiment of the present disclosure, the group III-V power semiconductor device, according to the present disclosure, is characterized in that the deactivated region is disposed throughout the entire region of the second capping layer.

In a further embodiment of the present disclosure, the group III-V power semiconductor device, according to the present disclosure, is characterized in that the deactivated region has a narrower width size than the second capping layer.

In a further embodiment of the present disclosure, the group III-V power semiconductor device, according to the present disclosure, is characterized in that a plurality of deactivated regions is disposed while being spaced apart from each other along a first direction in the second capping layer.

In a further embodiment of the present disclosure, the group III-V power semiconductor device, according to the present disclosure, is characterized in that the deactivated region has a stripe-pattern or island-pattern planar shape in the second capping layer.

In a further embodiment of the present disclosure, the group III-V power semiconductor device, according to the present disclosure, is characterized by further including an isolation film within the first and second regions, wherein the deactivated region is formed in conjunction with the isolation film through an ion implantation process.

In a further embodiment of the present disclosure, the group III-V power semiconductor device, according to the present disclosure, is characterized by further including: a drain electrode being spaced from the second capping layer within the second region; a first two-dimensional electron gas (2DEG) layer in the channel layer, below the deactivated region; and a second 2DEG layer in the channel layer, between the drain electrode and the second capping layer, wherein the first 2DEG layer has a lower concentration than the second 2DEG layer.

In a further embodiment of the present disclosure, the group III-V power semiconductor device, according to the present disclosure, is characterized in that the first region is an E-mode region, and the second region is a D-mode region.

In a further embodiment of the present disclosure, the group III-V power semiconductor device, according to the present disclosure, is characterized in that the deactivated region has a lower resistance than the second capping layer.

In one embodiment of the present disclosure, a method of manufacturing a group III-V power semiconductor device, according to the present disclosure, is characterized by including the following steps: sequentially forming a buffer layer, a channel layer, and a barrier layer on a substrate within a first region and a second region; forming a first capping layer within the first region and a deactivated region within a second capping layer of the second region; and forming a first gate electrode on the first capping layer and a second gate electrode on the deactivated region.

In one embodiment of the present disclosure, the method of manufacturing the group III-V power semiconductor device, according to the present disclosure, is characterized in that the first capping layer and the deactivated region are formed by the following steps: forming a first-conductivity type doped layer on the barrier layer; completing the first and second capping layers by etching the doped layer; and forming the deactivated region in the second capping layer by performing an ion implantation process.

In a further embodiment of the present disclosure, the method of manufacturing the group III-V power semiconductor device, according to the present disclosure, is characterized in that the deactivated region is disposed throughout the entire region of the second capping layer.

In a further embodiment of the present disclosure, the method of manufacturing the group III-V power semiconductor device, according to the present disclosure, is characterized by further including a step of forming an isolation film in the channel layer and the barrier layer within the first and second regions, before or after forming the deactivated region.

In one embodiment of the present disclosure, the method of manufacturing the group III-V power semiconductor device, according to the present disclosure, is characterized in that the step of forming the first capping layer and the deactivated region includes the following steps: forming a first-conductivity type doped layer on the barrier layer; forming a hard mask on the doped layer within the second region; completing the first and second capping layers by etching the doped layer; and forming the deactivated region in the second capping layer in conjunction with an isolation film within the first and second regions by performing an ion implantation process.

In one embodiment of the present disclosure, the method of manufacturing the group III-V power semiconductor device, according to the present disclosure, is characterized by further including a step of forming a first source electrode and a first drain electrode within the first region, and a second source electrode and a second drain electrode within the second region.

The present disclosure has the following effects based on the above-described configurations.

The present disclosure has an effect of implementing regions that differ from each other in threshold voltage characteristics on a single wafer.

In addition, the present disclosure has an effect of forming a deactivated region within a second region, thereby preventing damage to a barrier layer in advance when forming a gate electrode.

In addition, the present disclosure derives an effect of forming the entire region of a second capping layer to be formed within a second region as a deactivated region, thereby enabling regions that operate both in a D-mode and an E-mode to be formed on a single wafer.

In addition, the present disclosure shows an effect of enabling a deactivated region to be formed in conjunction with an isolation film through the same process in some cases, thereby preventing the overall process efficiency from being reduced.

In addition, the present disclosure shows an effect of enabling a deactivated region to be formed in various patterns in a second capping layer, thereby easily controlling the threshold voltage of a second region to a desired level.

In the meantime, it is further stated that even when not explicitly mentioned herein, the effects hereinafter expected by the technical features of the present disclosure and potential effects thereof are treated as those described herein of the present disclosure.

### BRIEF DESCRIPTION OF THE DRAWINGS

FIG. 1 is a plan view illustrating a group III-V power semiconductor device according to one embodiment of the present disclosure;

FIG. 2 is a cross-sectional view along the line AA′ of the group III-V power semiconductor device based on FIG. 1;

FIG. 3 is a reference cross-sectional view illustrating a deactivated region according to one embodiment of the present disclosure;

FIG. 4 is a reference cross-sectional view illustrating a deactivated region according to another embodiment of the present disclosure;

FIG. 5 is a reference cross-sectional view illustrating deactivated regions according to a further embodiment of the present disclosure;

FIGS. 6 and 7 are reference plan views illustrating formation patterns of deactivated regions;

FIG. 8 is a reference cross-sectional view showing an ohmic metal being formed on a second capping layer, and

FIGS. 9 to 21 are cross-sectional views illustrating a method of manufacturing a group III-V power semiconductor device according to one embodiment of the present disclosure.

### DETAILED DESCRIPTION

Hereinafter, embodiments of the present disclosure will be described in more detail with reference to the attached drawings. The embodiments of the present disclosure may be modified in various forms, and the scope of the present disclosure should not be construed as being limited to the following embodiments but should be construed on the basis of the appended claims. In addition, these embodiments are only provided for reference to more completely describe the present disclosure to those of ordinary skill in the art to which the present disclosure pertains.

Hereinafter, it should be noted that when one component (or layer) is described as being disposed on another component (or layer), one component may be disposed directly on another component, or another component(s) or layer(s) may be disposed between the components. In addition, when one component is expressed as being directly disposed on or above another component, no other component(s) are disposed between the components. Furthermore, being disposed “on”, “on an upper portion of”, “on a lower portion of”, “above”, “below”, “on one (first) side of”, or “on one side surface of” a component implies a relative positional relationship.

In addition, terms such as first, second, and the like may be used to describe various items, such as various elements, regions, and/or portions, but these items are not limited by such terms.

It should also be noted that when certain embodiments are implementable otherwise, certain processes may be performed in an order that differs from that described below. For example, two processes described sequentially may be substantially performed simultaneously or inversely.

Furthermore, a conductivity type or a doped region of components may be defined as “p-type” or “n-type” depending on the characteristics of main carriers, but this is only for the benefit of description, and the technical idea of the present disclosure is not limited as exemplified. For example, the more general term “first conductivity type” or “second conductivity type” will be used hereinafter for the “p-type” or “n-type”. In this case, the first conductivity type refers to the p-type, and the second conductivity type refers to the n-type.

It should also be understood that the terms “high concentration” and “low concentration” that express doping concentrations of impurity regions may refer to relative doping concentrations of one component and other components.

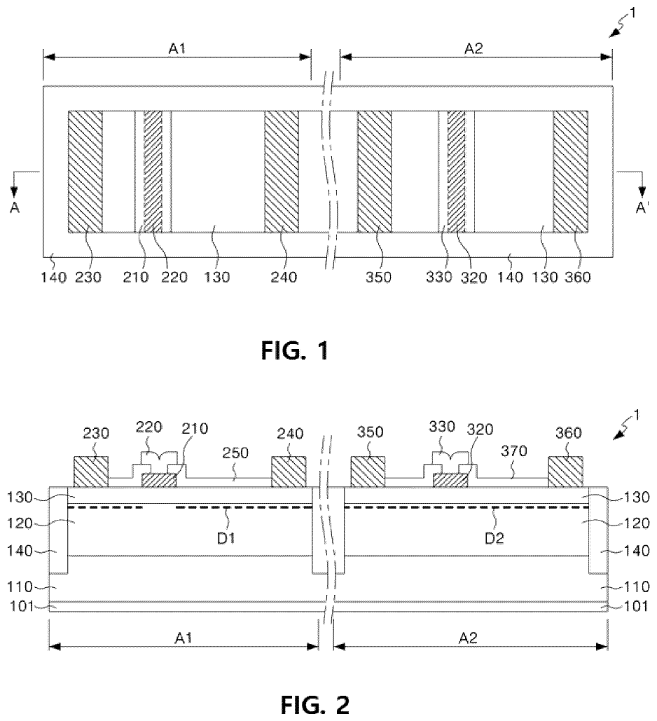

In addition, in the plan view illustrated in FIG. 1, an x-axis direction (the direction in which a gate electrode and a drain electrode are spaced apart) is set as a “first direction”, while a y-axis direction (the direction orthogonal to the x-axis direction on the same horizontal plane) is set as a “second direction”.

The following group III-V power semiconductor device is, for example, understood as a nitride-based semiconductor device.

FIG. 1 is a plan view illustrating a group III-V power semiconductor device according to one embodiment of the present disclosure, and FIG. 2 is a cross-sectional view along the line AA′ of the group III-V power semiconductor device based on FIG. 1. It should be noted that in the plan view illustrated in FIG. 1, the configuration of an insulation film is omitted.

Hereinafter, a group III-V power semiconductor device 1, according to one embodiment of the present disclosure, will be described in detail with reference to the attached drawings.

Referring to FIGS. 1 and 2, the present disclosure relates to the group III-V power semiconductor device 1. More particularly, the present disclosure relates to the power semiconductor device 1 in which regions that differ from each other in threshold voltage characteristics are implemented on a single wafer.

In one example, the group III-V power semiconductor device 1, according to one embodiment of the present disclosure, may enable E-mode and D-mode characteristics to be realized on the single wafer, but the scope of the present disclosure is not limited thereto.

The “E-mode” above refers to the normally-off operation mode of the device 1, while the “D-mode” above refers to the normally-on operation mode of the device 1. The “E-mode” enables the device 1 to be turned on with the application of positive voltage to a gate electrode. In addition, the “D-mode” enables the device 1 to be turned off with the application of negative voltage to a drain electrode and a source electrode.

As described above, the group III-V power semiconductor device 1, according to one embodiment of the present disclosure, implements the regions, for example, having E-mode and D-mode characteristics on the single wafer, and thus may be divided into a first region A1 having the E-mode characteristic and a second region A2 having the D-mode characteristic. Such first region A1 and second region A2 may be interconnected with each other. However, it should be noted that the second region A2 is not limited to the region having the D-mode characteristic.

First, the group III-V power semiconductor device 1, according to one embodiment of the present disclosure, may have a substrate 101. The substrate 101, which is a substrate for growth, may, for example, be a silicon substrate, but there are no limitations. Other examples thereof may include a sapphire substrate, a GaN substrate, or a SiC substrate. In the present disclosure, an example where the substrate 101 is a silicon substrate is to be described. Such a substrate 101 may be formed within both the first region A1 and the second region A2.

In addition, a buffer layer 110 may be formed on the substrate 101. The buffer layer 110 may be formed, for example, by growing AlN on the substrate 101 to a predetermined thickness. Alternatively, the buffer layer 110 may have a form in which a single layer of GaN or AlGaN or a composite layer of one or more of the foregoing GaN and AlGaN is grown, but there are no limitations. Such a buffer layer 110 may be a structure configured to prevent stress caused by differences in lattice constants and thermal expansion coefficients of the substrate 101 and a channel layer 120 to be described later. The buffer layer 110 may also be doped with impurities such as C and/or Fe. However, it should be noted that the buffer layer 110 is not an essential component of the present disclosure.

The channel layer 120 is formed to have a predetermined thickness on the substrate 101, more preferably on the buffer layer 110, and may, for example, be made of a semiconductor layer based on a nitride such as GaN. In addition, a barrier layer 130 is formed to have a predetermined thickness on the channel layer 120 and may, for example, be a semiconductor layer based on a nitride such as AlGaN. However, the scope of the present disclosure is not limited thereto. Such channel layer 120 and barrier layer 130 are preferably formed of nitride-based semiconductor layers that differ from each other. On the basis of such a structure, a 2DEG layer may be formed near the interface between the channel layer 120 and the barrier layer 130. In this case, the density and mobility of the 2DEG layer may be controlled by adjusting the Al and Ga contents in the barrier layer 130. In addition, the 2DEG layer may be formed in the channel layer 120. The buffer layer 110, the channel layer 120, and the barrier layer 130, described above, may be formed within both the first region A1 and the second region A2.

In addition, the channel layer 120 and the barrier layer 130 may be surrounded by an isolation film 140. The isolation film 140, which is configured to define an active region of the group III-V power semiconductor device 1 according to one embodiment of the present disclosure, may, for example, have a planar ring-like shape or a planar polygonal shape so that the channel layer 120 and the barrier layer 130 are surrounded, but there are no particular limitations. Such an isolation film 140 may be formed through ion implantation of one or more elements of Ar, N, O, Si, and H into the channel layer 120 and the barrier layer 130. In one example, the isolation film 140 may be formed such that the upper portion thereof is disposed on the surface of the barrier layer 130 while the lower portion thereof is disposed in the buffer layer 110. However, the scope of the present disclosure is not limited thereto. The isolation film 140 may be formed within both the first region A1 and the second region A2.

Hereinafter, a structure on the barrier layer 130 within the first region A1 will be described in detail.

A capping layer 210 may also be formed on the barrier layer 130 within the first region A1. The capping layer 210 is configured to be formed between the barrier layer 130 and a first gate electrode 220 to be described later. This capping layer 210 may cause depletion immediately below the first gate electrode 220, thus deactivating the 2DEG layer D1. Therefore, the first region A1 may operate in an E-mode. In addition, when the capping layer 210 is formed to a predetermined or larger thickness, the first gate electrode 220 and the 2DEG layer D1 become more distant, resulting in a longer response time. In contrast, when formed to a predetermined or smaller thickness, it is difficult to achieve the normally-off operation. Therefore, the thickness thereof is preferably formed at a suitable level, which is, for example, in the range of 10 nm to 1000 nm, but there are no limitations.

In addition, the capping layer 210 may be formed by growing a p-GaN layer, and the p-GaN layer may, for example, be formed by doping GaN with Mg. The capping layer 210 may also include a material formed by a difference in composition ratio based on a combination of x and y in an AlₓIn_{y}Ga_{1-x-y} material (x+y<1).

The first gate electrode 220 may also be formed on the capping layer 210. The first gate electrode 220 may, for example, be formed of a single layer or composite layer made of various metals, such as Ti and Pd. The depletion layer of the first gate electrode 220 may penetrate the barrier layer 130, reaching the channel layer 120 and thus blocking the 2DEG layer D1 to enable the normally-off operation of the device 1.

In addition, a first source electrode 230 and a first drain electrode 240 may be formed while being spaced from each other along the first direction with the first gate electrode 220 disposed therebetween. The first source electrode 230 and the first drain electrode 240 may be formed such that the lower portions thereof are disposed in the barrier layer 130, on the interface between the barrier layer 130 and the channel layer 120, in the channel layer 120, or on the barrier layer 130. However, there are no particular limitations.

Such first source electrode 230 and first drain electrode 240, which are ohmic contact regions, may, for example, have a square cross-sectional shape or a stepped cross-sectional shape. However, the scope of the present disclosure is not limited by any particular examples. In addition, the first source electrode 230 and the first drain electrode 240 may, for example, include a single layer or composite layer made of various metals capable of ohmic contact, such as Ti, Au, and Al. However, there are no particular limitations.

In addition, a first insulation film 250 may be formed on the barrier layer 130. The first insulation film 250 is preferably formed to be in contact with one side of the first gate electrode 220 while not covering the top surfaces of the first source electrode 230 and the first drain electrode 240. Furthermore, the first insulation film 250 may be made of an electrically insulating material, for example, Al₂O₃, but there are no particular limitations, and may also include any oxide film, nitride film, or the like.

Hereinafter, a structure on the barrier layer 130 within the second region A2 will be described in detail.

A deactivated region 320 may be formed on the barrier layer 130 within the second region A2. The deactivated region 320 is understood as a region where the function of a capping layer is lost. Such a deactivated region 320 may be formed, for example, by forming a layer that is the same as the capping layer 210 on the barrier layer 130 and then performing an ion implantation process on the same layer. In one example, when the p-GaN layer is grown on the barrier layer 130 and then etched in a pattern substantially the same as the capping layer 210, a second capping layer 310 may be formed on the barrier layer 130 within the second region A2. The capping layer 210 to be formed within the first region A1 is referred to as a first capping layer 210. Subsequently, at least a partial region of the second capping layer 310 may be deactivated by performing an ion implantation process in the second capping layer 310. Such a deactivated region 320 may have a lower hole concentration than the first capping layer 210.

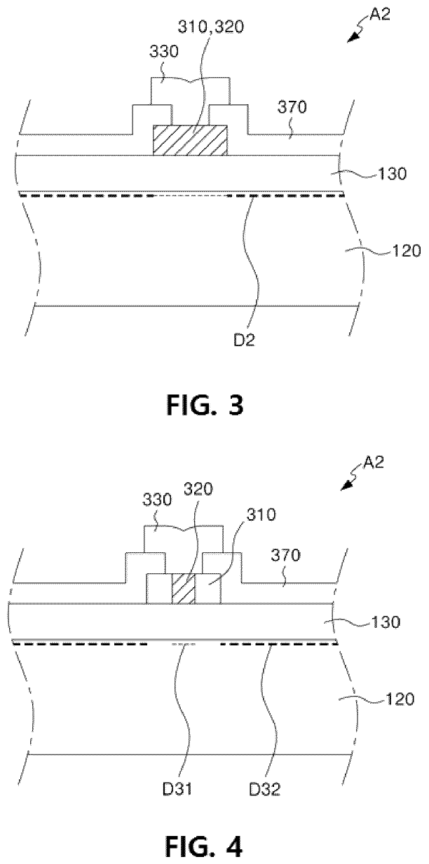

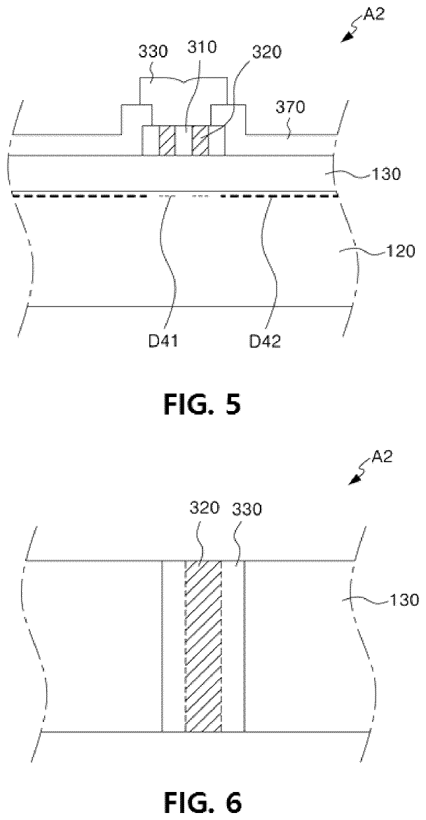

FIG. 3 is a reference cross-sectional view illustrating a deactivated region according to one embodiment of the present disclosure, FIG. 4 is a reference cross-sectional view illustrating a deactivated region according to another embodiment of the present disclosure, and FIG. 5 is a reference cross-sectional view illustrating deactivated regions according to a further embodiment of the present disclosure.

Referring to FIG. 3, the deactivated region 320 may, for example, be formed throughout the entire region of the second capping layer 310. In this case, the second capping layer 310 is completely deactivated, so the device 1 may operate in a D-mode within the second region A2. Thus, within the second region A2, a 2DEG layer D2 may be elongated uninterruptedly along the first direction.

Referring to FIG. 4, the deactivated region 320 may be formed in the second capping layer 310, only in a partial region of the second capping layer 310, in another example. In other words, the deactivated region 320 preferably has a narrower width size along the first direction than the second capping layer 310. For example, the deactivated region 320 may be formed substantially around the center of the second capping layer 310. The expression “formed substantially around the center” above is understood to mean formed around the center in the second capping layer 310 within the alignment error range of a mask pattern to be utilized when forming the deactivated region 320. In this case, a 2DEG layer D31 in the channel layer 120 may have a lower concentration (=higher resistance) than a 2DEG layer D32 that does not overlap with the deactivated region 320 along the vertical direction.

Referring to FIG. 5, a plurality of deactivated regions 320 may be formed in the second capping layer 310 while being spaced apart from each other along the first direction, in a further example. In this case, a 2DEG layer D41 in the channel layer 120 may have a lower concentration (=higher resistance) than a 2DEG layer D42 that does not overlap with the deactivated region 320 along the vertical direction.

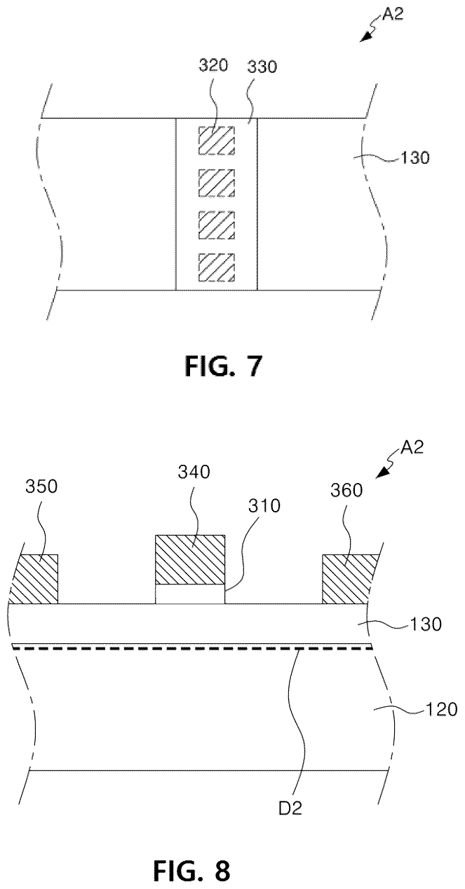

FIGS. 6 and 7 are reference plan views illustrating formation patterns of deactivated regions.

In addition, when the deactivated region 320 is formed only in the partial region in the second capping layer 310, the deactivated region 320 may be formed in a stripe pattern along the second direction (see FIG. 6), or the plurality thereof may be formed in an island pattern while being spaced apart from each other along the second direction (see FIG. 7). However, there are no particular limitations.

By forming the deactivated region 320 in various patterns as described above, the threshold voltage characteristics of the device 1 can be obtained to a desired level within the second region A2.

Referring to FIGS. 1 and 2, the deactivated region 320 may be formed, for example, through ion implantation of one or more elements of Ar, N, O, Si, and H into the second capping layer 310. In one example, the ion implantation of H element into the second capping layer 310 may passivate the second capping layer 310 made of Mg-doped GaN. Therefore, the hole concentration in the second capping layer 310 may be reduced.

In another example, the ion implantation of elements such as Ar and/or N into the second capping layer 310 may cause lattice damage in the second capping layer 310 based on p-GaN, thereby reducing the polarization charge of the second capping layer 310. In addition, the ion implantation of H element into the second capping layer 310 at high energy and/or high concentration may cause lattice damage in the second capping layer 310.

In addition, the ion implantation process for forming the deactivated region 320 may be performed in conjunction with the ion implantation process for forming the isolation film 140. In other words, a single mask pattern may be utilized to form the deactivated region 320 and the isolation film 140. Accordingly, the deactivated region 320 can be formed without any additional process, thereby preventing the overall process efficiency from being reduced. In this case, ion implantation of one or more elements of Ar, N, O, Si, and H may be performed on the side where the deactivated region 320 and the isolation film 140 are to be formed. In addition, the deactivated region 320 may have a lower doping concentration of the element to be implanted through ion implantation than the isolation film 140.

Alternatively, the deactivated region 320 may be formed in a separate process from the isolation film 140. In this case, a separate mask pattern may be utilized to form the deactivated region 320. Furthermore, in this process, the elements implanted during each of the ion implantation processes for forming the deactivated region 320 and the isolation film 140 may be different or the same, but there are no particular limitations.

By forming the deactivated region 320 within the second region A2 as described above, both regions A1 and A2 that differ from each other in threshold voltage characteristics can be formed in conjunction on the single wafer. In addition, the deactivated region 320 may be formed before forming a second gate electrode 330 to be described later, thereby protecting the barrier layer 130 below the deactivated region 320. In a group III-V power semiconductor device that typically operates in a D-mode, a gate electrode is formed on a barrier layer while being in contact therewith. While a gate electrode is formed by depositing a metal film and performing an etching process, damage to a barrier layer may occur during the etching process. To prevent such damage, the deactivated region 320 of the group III-V power semiconductor device 1, according to one embodiment of the present disclosure, may be configured to protect the barrier layer 130 when etching the second gate electrode 330.

Referring to FIGS. 1 and 2, the second gate electrode 330 may be formed on the second capping layer 310 and/or the deactivated region 320. Such a second gate electrode 330 may be configured substantially in the same manner as the first gate electrode 220.

FIG. 8 is a reference cross-sectional view showing an ohmic metal being formed on the second capping layer.

Referring to FIG. 8, in another embodiment, an ohmic metal 340 may be formed on the second capping layer 310. In this case, the ohmic metal 340 may be formed in conjunction during processes for forming a second source electrode 350 and a second drain electrode 360, which will be described later, and preferably includes the same material as both electrodes 350 and 360, which is more preferably made of the same material. In addition, when forming the ohmic metal 340, the deactivated region 320 may not be formed in the second capping layer 310.

Furthermore, referring to FIGS. 1 and 2, the second source electrode 350 and the second drain electrode 360 may be formed while being spaced from each other along the first direction. Such second source electrode 350 and second drain electrode 360 are configured substantially in the same manner as the first source electrode 230 and the first drain electrode 240, so the detailed descriptions thereof will be omitted.

In addition, a second insulation film 370 may be formed on the barrier layer 130. The second insulation film 370 is configured substantially in the same manner as the first insulation film 250, so the detailed description thereof will be omitted.

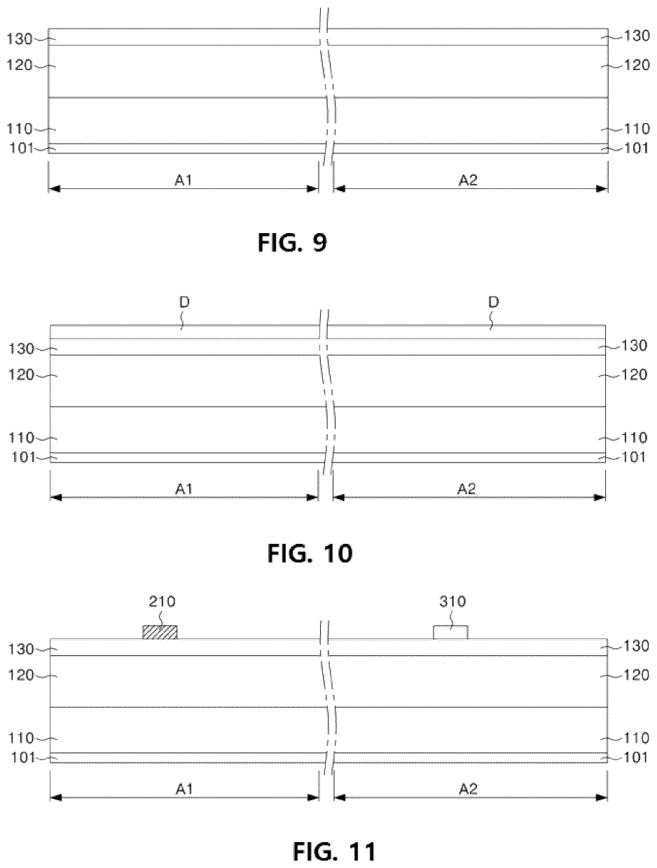

FIGS. 9 to 21 are cross-sectional views illustrating a method of manufacturing a group III-V power semiconductor device according to one embodiment of the present disclosure.

Hereinafter, a method of manufacturing a group III-V power semiconductor device 1, according to one embodiment of the present disclosure, will be described in detail with reference to the attached drawings.

Referring to FIG. 9, a buffer layer 110, a channel layer 120, and a barrier layer 130 may first be formed sequentially on a substrate 101 within a first region A1 and a second region A2. The substrate 101, which is a substrate for growth as described above, may be any one of a silicon substrate, a sapphire substrate, a GaN substrate, and a SiC substrate, but the description in the present disclosure is based on one example being a silicon substrate. The buffer layer 110 may be formed on the substrate 101 and under the channel layer 120, for example, by growing an AlN layer to a predetermined thickness. In addition, the channel layer 120 to be formed on the buffer layer 110 is a semiconductor layer based on a nitride such as GaN, and the barrier layer 130 is a semiconductor layer based on a nitride such as AlGaN. By electrons accumulated at the interface between the channel layer 120 and the barrier layer 130, a 2DEG layer may be formed.

For a detailed description, piezoelectric polarization may occur at the interface between the channel layer 120 and the barrier layer 130, for example, due to differences in lattice constants of GaN and AlGaN. In this case, the piezoelectric polarization effect and the spontaneous polarization effect of the channel layer 120 and the barrier layer 130 may function, thereby generating two-dimensional electron gas with a high electron concentration at the interface between the two configurations.

Then, on the barrier layer 130, a first capping layer 210 may be formed within the first region A1, while a deactivated region 320 may be formed within the second region A2. In addition, as needed, a second capping layer 310 may be formed within the second region A2, and the deactivated region 320 may be formed in a partial region of the second capping layer 310.

Referring to FIG. 10, to this end, a doped layer D, for example, in which a GaN layer is grown with the first conductivity type, may be first formed on the barrier layer 130. Such a doped layer D may be formed within both the first region A1 and the second region A2.

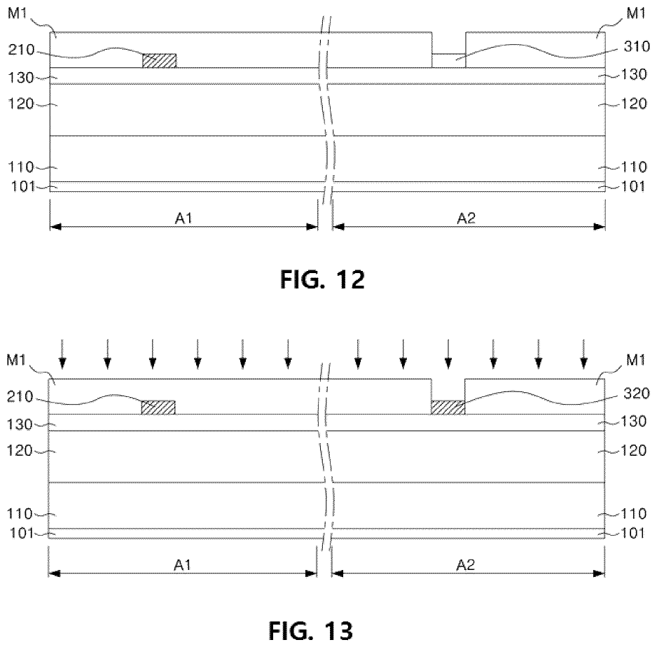

Referring to FIG. 11, a mask pattern (not shown) may, for example, be utilized afterward to perform an etching process on the doped layer D. By this process, the first capping layer 210 may be completed within the first region A1, while the second capping layer 310 may be completed within the second region A2. Then, a deactivation process is performed on at least a partial region of the second capping layer 310. Hereinafter, the deactivation process is to be described in detail. Referring to FIG. 12, a first mask pattern M1 is formed on the barrier layer 130 within the second region A2. The first mask pattern M1 may be formed in such a shape that at least a portion of the top surface of the second capping layer 310 is exposed.

Referring to FIG. 13, an ion implantation process may then be performed in the second capping layer 310 to form the deactivated region 320 in the second capping layer 310. The ion implantation process for forming the deactivated region 320 is covered by the above description. As described above, the deactivated region 320 may be formed throughout the entire region of the second capping layer 310 or only in the partial region of the second capping layer 310. Alternatively, a plurality thereof may be formed in the second capping layer 310 while being spaced apart from each other. However, the scope of the present disclosure is not limited by any particular examples.

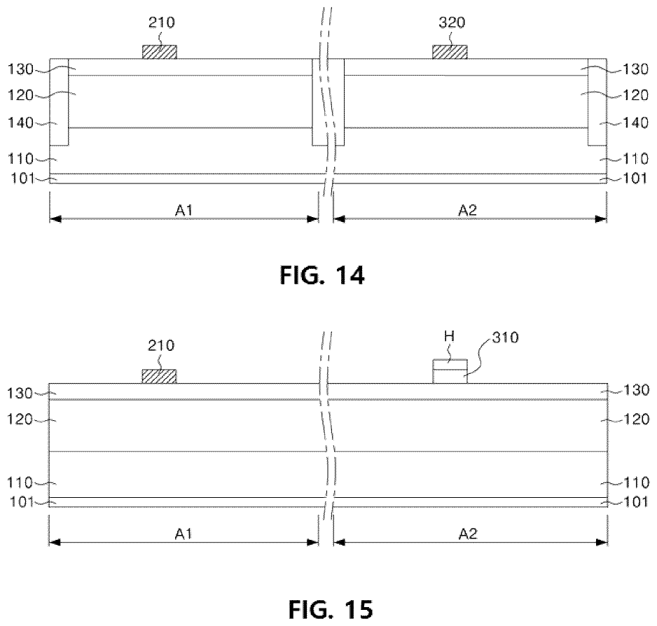

Referring to FIG. 14, an isolation film 140 may be formed thereafter within the first region A1 and the second region A2. The isolation film 140 may be formed by performing an ion implantation process utilizing a mask pattern (not shown) on the barrier layer 130. In some cases, the process for forming the isolation film 140 may also be performed in advance of the formation of the deactivated region 320.

Referring to FIG. 15, a hard mask H may be formed on the doped layer D, in another example. The hard mask H may be completed by depositing an oxide film, a nitride film, an oxynitride film, or a metal film on the doped layer D and then performing an etching process. Then, the doped layer D may be etched such that the first capping layer 210 is formed within the first region A1 while the second capping layer 310 is formed within the second region A2. In this case, the hard mask H may be disposed on the second capping layer 310.

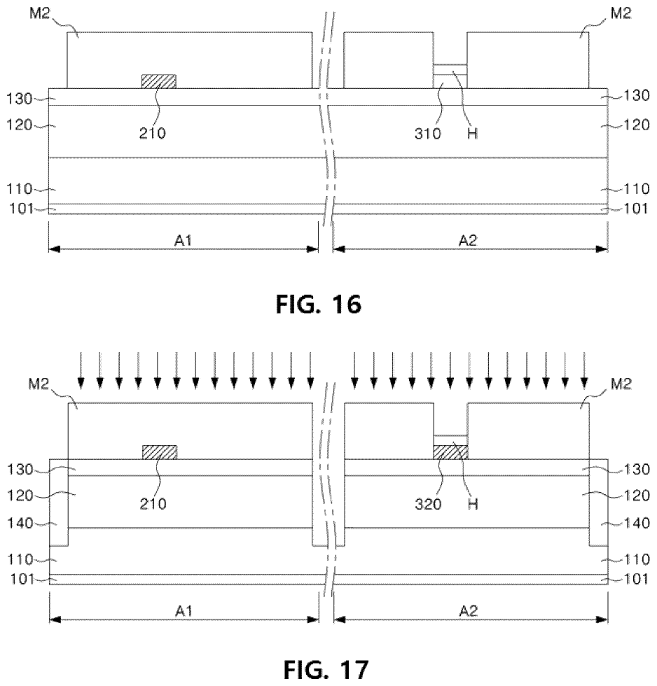

Then, a deactivation process may be performed on at least a partial region of the second capping layer 310. This will be described in detail. Referring to FIG. 16, a second mask pattern M2 is formed on the barrier layer 130 within the second region A2. The second mask pattern M2 may be formed in such a shape that at least a portion of the top surface of the hard mask H is exposed. In addition, the second mask pattern M2 may be formed in such a shape that the top surface of the barrier layer 130 on the side where the isolation film 140 is to be formed is exposed.

Referring to FIG. 17, an ion implantation process may then be performed in the second capping layer 310 to form the deactivated region 320 in the second capping layer 310. In addition, the isolation film 140 may be formed in conjunction in this process. As described above, the deactivated region 320 may be formed throughout the entire region of the second capping layer 310 or only in the partial region of the second capping layer 310. Alternatively, a plurality thereof may be formed in the second capping layer 310 while being spaced apart from each other. However, the scope of the present disclosure is not limited by any particular examples.

Once the deactivated region 320 is completed, the hard mask H may be removed.

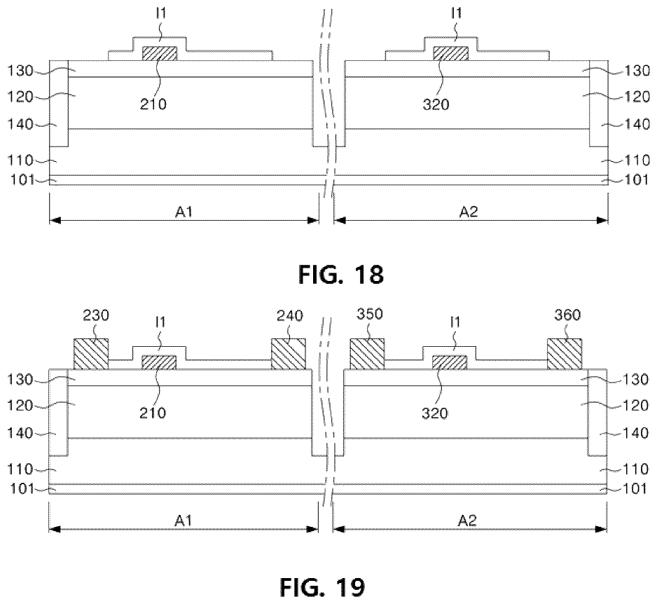

Referring to FIG. 18, a first insulation layer I1 may then be formed on the barrier layer 130 within the first region A1 and the second region A2. The first insulation layer I1 may be deposited on the barrier layer 130 so that the first capping layer 210 and the deactivated region 320 are covered. Subsequently, the first insulation layer I1 on the side where a first source electrode 230, a first drain electrode 240, a second source electrode 350, and a second drain electrode 360 are to be formed may be etched. Such a first insulation layer I1 may be made of an electrically insulating material and may, for example, include an oxide film, a nitride film, or an oxynitride film.

Referring to FIG. 19, the first source electrode 230, the first drain electrode 240, the second source electrode 350, and the second drain electrode 360 may be formed thereafter. Such electrodes 230, 240, 350, and 360 may be formed by depositing a metal film on the first insulation layer I1 and performing an etching process.

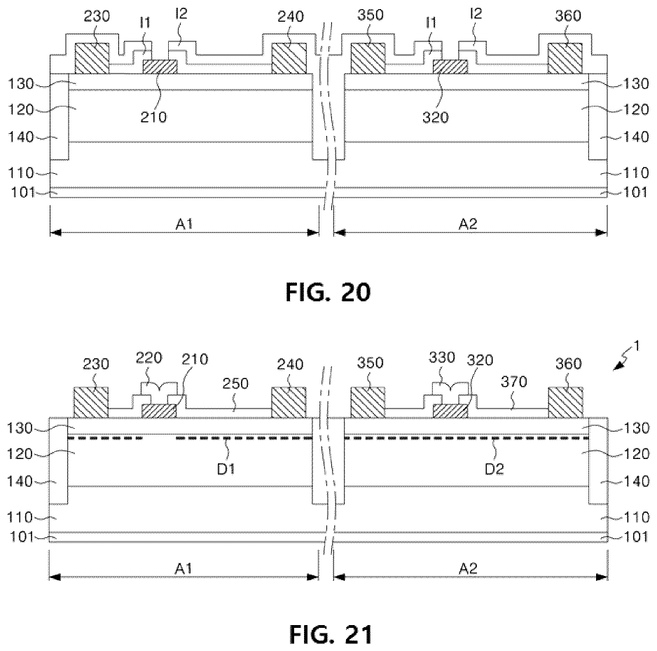

Referring to FIG. 20, a second insulation layer 12 may then be deposited on the first insulation layer I1, followed by performing an etching process. By this process, one side of the first capping layer 210, as well as one side of the second capping layer 310 or the deactivated region 320, may be exposed.

Referring to FIG. 21, a first gate electrode 220 and a second gate electrode 330 may then be completed by depositing a metal film on the second insulation layer 12 and performing an etching process.

The detailed description above is illustrative of the present disclosure. In addition, the description above shows and describes preferred embodiments of the present disclosure, and the present disclosure can be used in various other combinations, modifications, and environments. In other words, changes or modifications are possible within the scope of the concept of the disclosure disclosed herein, the scope equivalent to the written disclosure, and/or the scope of skill or knowledge in the art to which the present disclosure pertains. The above-described embodiments describe the best state for implementing the technical idea of the present disclosure, and various changes required in the specific application field and use of the present disclosure are possible. Therefore, the detailed description of the present disclosure above is not intended to limit the present disclosure to the embodiments disclosed herein.

What is claimed is:

1. A group III-V power semiconductor device comprising:
a first region;
a second region having a threshold voltage that differs from that of the first region;
a substrate in the first and second regions;
a channel layer on the substrate in the first and second regions;
a barrier layer on the channel layer in the first and second regions;
a capping layer on the barrier layer in the first region;
a first gate electrode on the capping layer;
a deactivated region on the barrier layer in the second region; and
a second gate electrode on the deactivated region.

2. The power semiconductor device of claim 1, wherein the second region is a depletion mode (D-mode) region.

3. The power semiconductor device of claim 1, wherein the deactivated region comprises an ion implantation region.

4. The power semiconductor device of claim 3, wherein the ion implantation region comprises one or more of Ar, N, O, Si, and H.

5. A group III-V power semiconductor device comprising:
a first region;
a second region having a threshold voltage that differs from that of the first region;
a substrate in the first and second regions;
a channel layer on the substrate in the first and second regions;
a barrier layer on the channel layer in the first and second regions;
a first capping layer on the barrier layer in the first region;
a first gate electrode on the first capping layer;
a second capping layer on the barrier layer in the second region;
a deactivated region in the second capping layer; and
a second gate electrode on the deactivated region.

6. The power semiconductor device of claim 5, wherein the deactivated region comprises an ion implantation region in the second capping layer.

7. The power semiconductor device of claim 5, wherein the deactivated region is throughout the entire second capping layer.

8. The power semiconductor device of claim 5, wherein the deactivated region has a narrower width than the second capping layer.

9. The power semiconductor device of claim 8, comprising a plurality of deactivated regions spaced apart from each other along a first direction in the second capping layer.

10. The power semiconductor device of claim 8, wherein the deactivated region has a stripe-pattern or island-pattern shape.

11. The power semiconductor device of claim 5, further comprising:
an isolation film in the first and second regions,
wherein the deactivated region comprises ion implantation region.

12. The power semiconductor device of claim 5, further comprising:
a drain electrode in the second region, spaced from the second capping layer;
a first two-dimensional electron gas (2DEG) layer in the channel layer, below the deactivated region; and
a second 2DEG layer in the channel layer, between the drain electrode and the second capping layer,
wherein the first 2DEG layer has a lower concentration than the second 2DEG layer.

13. The power semiconductor device of claim 5, wherein the first region is an enhancement-mode (E-mode) region, and the second region is a depletion mode (D-mode) region.

14. The power semiconductor device of claim 5, wherein the deactivated region has a lower resistance than the second capping layer.

15. A method of manufacturing a group III-V power semiconductor device, the method comprising:
sequentially forming a buffer layer, a channel layer, and a barrier layer on a substrate in a first region and a second region;
forming a first capping layer in the first region and a deactivated region in a second capping layer of the second region; and
forming a first gate electrode on the first capping layer and a second gate electrode on the deactivated region.

16. The method of claim 15, wherein forming the first capping layer and the deactivated region comprises:
forming a first-conductivity type doped layer on the barrier layer;
completing the first and second capping layers by etching the doped layer; and
forming the deactivated region by performing an ion implantation process in the second capping layer.

17. The method of claim 16, wherein the deactivated region is throughout the entire second capping layer.

18. The method of claim 16, further comprising:
forming an isolation film in the channel layer and the barrier layer in the first and second regions, before or after forming the deactivated region.

19. The method of claim 15, wherein forming the first capping layer and the deactivated region comprises:
forming a first-conductivity type doped layer on the barrier layer;
forming a hard mask on the doped layer in the second region;
completing the first and second capping layers by etching the doped layer; and
forming the deactivated region in the second capping layer in conjunction with an isolation film in the first and second regions by performing an ion implantation process.

20. The method of claim 15, further comprising forming a first source electrode and a first drain electrode in the first region, and a second source electrode and a second drain electrode in the second region.
